(19) United States
(12) Patent Application Publication
(10) Pub. No.: US 2022/0205133 A1
(43) Pub. Date: Jun. 30, 2022

(54) ENHANCED DOPING USING ALLOY BASED SOURCES

(71) Applicant: Aledia, Grenoble (FR)

(72) Inventors: Olga Kryliouk, Fort Myers, FL (US); Walf Chikhaoui, Voiron (FR); Jerome Napierala, Saint Egréve (FR); Vishnuvarthan Kumaresan, Voiron (FR)

(73) Assignee: Aledia, Grenoble (FR)

(21) Appl. No.: 17/606,189

(22) PCT Filed: Apr. 23, 2020
(86) PCT No.: PCT/US2020/029554

§ 371 Date: Oct. 25, 2021

Related U.S. Application Data
(60) Provisional application No. 62/838,817, filed on Apr. 25, 2019.

(51) Int. Cl. C30B 25/02; C23C 16/30; C30B 23/02; C30B 29/40; H01L 21/02

(52) U.S. Cl. CPC C30B 25/02; C23C 16/303; C30B 23/02; H01L 21/0262; H01L 21/0254; H01L 21/02631; C30B 29/406

(57) ABSTRACT

Deposition methods using a Ga-based alloy to incorporate dopants into GaN-based materials are generally described.

### TECHNICAL FIELD

Deposition methods using a gallium (Ga)-based alloy to incorporate dopants into GaN-based materials are generally described.

### BACKGROUND

Chemical deposition processes are used to deposit layers (e.g., thin films) that can be used, for example, in semiconductor devices. Molecular beam epitaxy (MBE) and hydride vapor phase epitaxy (HVPE) are deposition processes that may have certain advantages over other conventional deposition processes, such as metal-organic chemical vapor deposition (MOCVD). For example, certain advantages of MBE include precise thickness control of the deposition layer and avoiding the need for the activation of precursor components, and certain advantages of HVPE include high growth rate and high purity of deposition layers.

Semiconductor devices may include a variety of different material layers. Gallium nitride (GaN)-based material layers, for example, are often used in certain semiconductor devices such as light-emitting diodes (LEDs). Dopants (e.g., n-type or p-type dopants) are often introduced into GaN-based materials to alter certain electric properties of the material in order to improve device performance and operation. For example, high doping levels may result in a material with improved operating voltages, current injection efficiencies, and/or current spreading (e.g., throughout the material).

The deposition of GaN-based materials using MBE and/or HVPE is well known, but the incorporation of p-type dopants (e.g., magnesium (Mg)) into GaN-based materials is challenging. Native point defects in the semiconductor material, such as interstitial atoms and ions, may react with p-type dopants. The resulting dopant-based point defect complexes are electrically inactive in GaN-based materials, and act as single donors that may be responsible for unwanted emissions. For example, Mg-based point defect complexes may produce broad red emissions at 1.8 eV in GaN-based materials.

Accordingly, improved methods are needed for the deposition of GaN-based materials with high levels of effective p-type dopants.

### SUMMARY

Deposition methods using a Ga-based alloy to incorporate dopants into GaN-based materials are generally described.

Certain embodiments are related to a deposition method, wherein the method comprises providing a first material comprising a N-based source, providing a second material comprising a Ga-based alloy, wherein the Ga-based alloy comprises Ga and at least one alloying element, and depositing a layer comprising a GaN-based material comprising the at least one alloying element as a dopant onto a surface of a substrate.

Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention. In the figures:

FIG. 1 shows a schematic representation of the series of steps involved in a deposition process, according to certain embodiments;

FIG. 2 shows a schematic representation of the series of steps involved in an MBE process, according to certain embodiments;

FIG. 3 shows a schematic representation of the series of steps involved in an HVPE process, according to certain embodiments;

FIG. 4A shows a non-limiting temperature-composition phase-diagram of a Ga-based alloy comprising Mg;

FIG. 4B shows a non-limiting diagram of various possible compositions of a ternary Ga-based alloy comprising Mg and Al at 300° C.; and

FIG. 4C shows a non-limiting temperature-composition phase-diagram of a Ga-based alloy comprising Mg and Al.

### DETAILED DESCRIPTION

The deposition of GaN-based materials using Ga-based alloys is generally described herein. The Inventors have realized and appreciated that a Ga-based alloy comprising gallium and at least one alloying element can be used as a precursor source in a MBE process to deposit a GaN-based material layer that includes the alloying element as a dopant. Accordingly, the Ga-based alloy can replace conventional dopant sources, such as a single metal (e.g., Ga, Mg), that may have the potential to react with native defects in the material layer. Other deposition techniques, such as HVPE, can similarly be modified to use Ga-based alloys as replacements for conventional precursor sources (e.g., a single metal, a dopant such as bis(cyclopentadienyl)magnesium (Cp₂Mg)). The Ga-based alloys may be eutectic compositions with one or more eutectic points. The implementation of Ga-based alloys as precursor sources for deposition has the potential to provide more appropriately doped semiconductor materials with increased device performance and operation. Such semiconductor materials can be used, for example, as transistors, solar cells, and/or light-emitting diodes.

Methods related to the deposition of layers (e.g., thin-films) are described herein. According to certain embodiments, methods related to depositing layers may generally comprise a series of standard steps. In certain embodiments, for example, the deposition method may comprise providing a substrate and arranging the substrate in an evacuable chamber and/or reactor. The method may further comprise reducing the chamber and/or reactor pressure (e.g., to less than or equal to 10⁻⁵ torr and greater than or equal to 10⁻¹² torr), such as in the case of MBE. In certain embodiments, the deposition method may comprise an optional step of heating the substrate to cause desorption of contaminants from the growth surface, followed by adjusting the substrate temperature to that desired for growth of the layer, which may take place after arranging the substrate in the chamber and/or reactor.

In some embodiments, the deposition method may be related to MBE. In certain other embodiments, the method of deposition may be related to HVPE. MBE and HVPE are explained in greater detail herein. In some embodiments, the methods described herein are particularly well-suited for MBE processes.

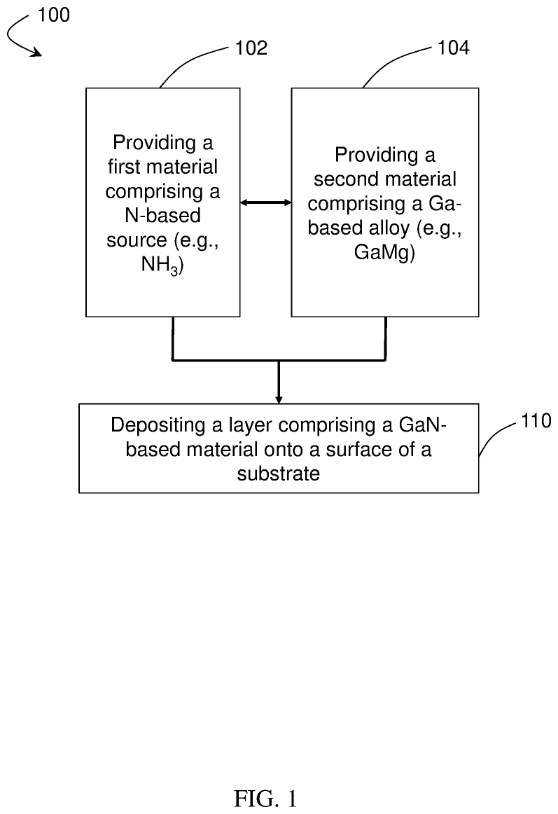

According to some embodiments, the deposition method may involve providing a N-based source and a Ga-based alloy source. FIG. 1 shows a schematic representation of the series of steps involved in a deposition process, according to certain embodiments. As shown in FIG. 1, deposition method 100 comprises step 102 comprising providing a first material comprising a N-based source. In certain embodiments, the N-based source may be provided as a gaseous composition. Suitable materials comprising a N-based source will be explained herein in greater detail. As shown in FIG. 1, step 104 comprises providing a second material comprising a Ga-based alloy. In certain embodiments, the Ga-based alloy may be a eutectic composition. In some embodiments, the second material may comprise more than one Ga-based alloys (e.g., two Ga-based alloys, three Ga-based alloys, etc.). In certain aspects, providing the second material may comprise evaporating and/or vaporizing the second material into a gaseous composition. In some embodiments, the Ga-based alloy comprises Ga and at least one alloying element. In some aspects, the Ga-based alloy may comprise Ga and at least one other Group III element (e.g., Al and/or In), in addition to the other alloying element. Additional details regarding the Ga-based alloy are described herein in greater detail. According to certain embodiments, steps 102 and 104 of method 100 may occur simultaneously. In certain other embodiments, steps 102 and 104 of method 100 may occur at different times (e.g., subsequent to one another).

In certain embodiments, at least the first material and the second material may chemically react to provide a product comprising a GaN-based material. For example, in some embodiments, at least the first material comprising a N-based source that is provided as a gaseous composition may react with the second material comprising a Ga-based alloy that has been evaporated and/or vaporized into a second gaseous composition to provide a product comprising the GaN-based material that includes at least one alloying element as a dopant. According to some embodiments, in reference to FIG. 1, the deposition method may further comprise step 110 comprising depositing a layer comprising the GaN-based material that includes at least one alloying element as a dopant onto a surface of a substrate.

It should be understood that GaN-based materials, as used herein, refers to gallium nitride (GaN) or one of its alloys, such as aluminum gallium nitride (AlGaN), indium gallium nitride (InGaN), and aluminum indium gallium nitride (AlInGaN).

According to certain embodiments, one or more steps of the deposition method (e.g., providing and/or depositing) are performed under suitable vacuum conditions. For example, according to certain embodiments, the vacuum may have a pressure of less than or equal to 10⁻⁵ torr. Suitable vacuum conditions may be employed during methods related to MBE. Alternatively, in some embodiments, one or more steps of the deposition method may be performed at atmospheric pressure. For example, in some embodiments related to HVPE, one or more deposition steps may be performed at 760 torr.

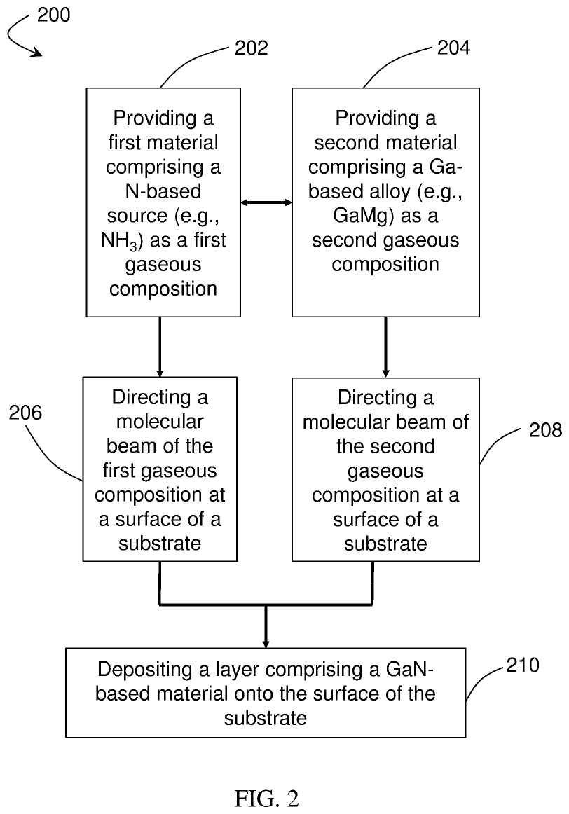

As noted above, the methods described herein may be particularly well-suited for an MBE process. FIG. 2 shows a schematic representation of the series of steps involved in an exemplary MBE process, according to certain embodiments. In some aspects, MBE method 200 may comprise step 202 comprising providing a first material comprising a N-based source as a first gaseous composition and step 204 comprising providing a second material comprising a Ga-based alloy as a second gaseous composition. In certain embodiments, providing may comprise loading cells (e.g., shuttered effusion cells) with the requisite source materials for deposit growth. In certain embodiments, where appropriate, the cells may be heated in order to evaporate and/or vaporize one or more source materials into a gaseous composition (e.g., the second material comprising a Ga-based alloy may be evaporated and/or vaporized into a gaseous composition). According to certain embodiments, steps 202 and 204 of method 200 may occur simultaneously. In certain other embodiments, steps 202 and 204 of method 200 may occur at different times (e.g., subsequent to one another).

In some embodiments, MBE method 200 may further comprise directing a molecular beam of the first gaseous composition and the second gaseous composition at a surface of a substrate (e.g., see steps 206 and 208). In certain embodiments, steps 206 and 208 of MBE method 200 take place after steps 202 and 204, respectively. In some aspects, steps 206 and 208 may occur simultaneously.

According to certain embodiments, MBE method 200 may further comprise step 210 comprising depositing a layer (e.g., an epitaxial layer) comprising a GaN-based material onto the surface of the substrate. The layer may be deposited until the desired deposition layer (e.g., epitaxial layer) thickness is attained. In certain embodiments, the molecular beam of the first gaseous composition in step 206 and the molecular beam of the second gaseous composition in step 208 may be directed to meet (e.g., where the molecular beam of the first gaseous composition and the molecular beam of the second gaseous composition cross paths) at the surface of the substrate. In some such embodiments, the molecular beam of the first gaseous composition and the molecular beam of the second gaseous composition react to form a product comprising the GaN-based material as step 210 is taking place (e.g., as the product comprising the GaN-based material is deposited onto the surface of the substrate as a layer).

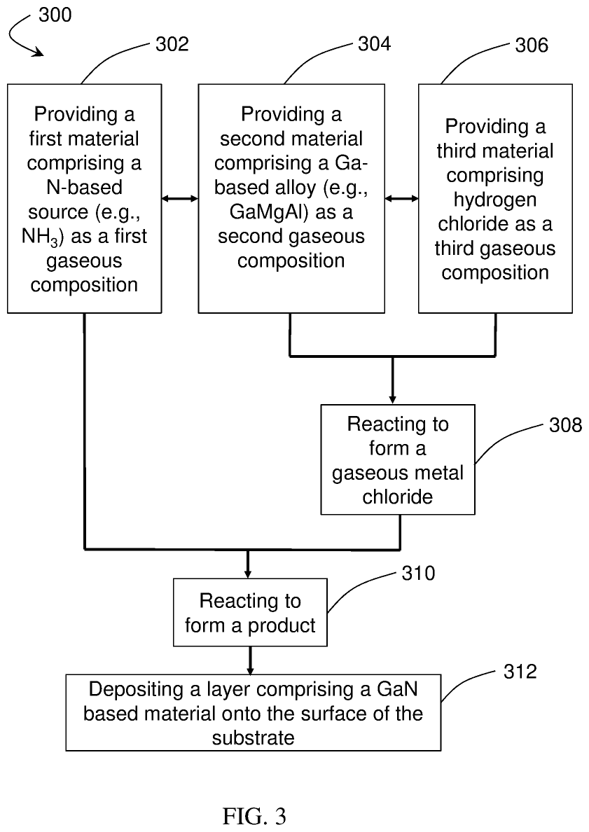

As noted above, the techniques described herein may also be used in a HVPE process. FIG. 3 shows a schematic representation of the series of steps involved in a HVPE process, according to certain aspects. In some embodiments, HVPE method 300 may comprise step 302 comprising providing a first material comprising a N-based source as a first gaseous composition, step 304 comprising providing a second material comprising a Ga-based alloy, and step 306 comprising providing a third material comprising hydrogen chloride (HCl) as a third gaseous composition. In certain embodiments, the third material may comprise chlorine gas (Cl₂). In certain embodiments, step 304 may comprise evaporating and/or vaporizing a second material comprising a ternary Ga-based alloy into a second gaseous composition. In certain embodiments, providing may comprise loading the chamber and/or reactor of the HVPE system with the requisite source materials for deposit growth. In certain embodiments, where appropriate, the chamber and/or reactor may be heated in order to evaporate and/or vaporize one or more source materials into a gaseous composition (e.g., the second material comprising a Ga-based alloy may be evaporated and/or vaporized into a gaseous composition). In some embodiments, steps 302, 304, and/or 306 of method 300 may occur simultaneously. In other embodiments, steps 302, 304, and 306 of method 300 may occur at different times (e.g. subsequent to one another).

In certain embodiments, the HVPE method further comprises initiating vapor-phase reaction(s) between the source materials. For example, in some embodiments, step 308 comprises reacting the third gaseous composition arising from step 306 and the second gaseous composition arising from step 304. Additionally, in some aspects, step 310 comprises reacting the first gaseous composition and the metal-chloride resulting from step 308 to from a product comprising the GaN-based material. According to certain embodiments, steps 308 and/or 310 may comprise reacting in the vapor phase. In some embodiments, step 308 may take place before, during, and/or after step 302.

Additionally, in certain embodiments, the method related to HVPE may comprise depositing a layer (e.g., epitaxial layer) of the product comprising the GaN based material onto a surface of a substrate. For example, as shown in FIG. 3, method 300 further comprises step 312 comprising depositing a layer of the product arising from step 310 onto a surface of a substrate. According to certain embodiments, step 310 and step 312 may take place simultaneously. In some embodiments, for example, the first gaseous product arising from step 302 may react with the gaseous metal chloride arising from step 308 to form a product, as a layer of the product is being deposited onto the surface of the substrate.

As noted above, the methods may utilize a N-based source. For example, in some embodiments, the N-source may comprise ammonia (NH₃), nitrogen gas (N₂), and/or hydrazine (N₂H₄). Other N-based sources may also be possible.

The methods may also utilize a Ga-based alloy source. A Ga-based alloy, for example, comprises Ga metal (and, in some cases, other Group III elements such as Al and/or In) and at least one alloying element (at least one metal and/or at least one non-metal). According to some embodiments, the Ga-based alloy is a eutectic composition such that the composition is a homogeneous mixture that melts or solidifies at a single temperature (e.g., the eutectic point) that is lower than the melting point the constituents of the composition. As described herein, the Ga-based alloy may be the source of Ga (and, in some cases, other Group III elements such as Al and/or In) that is provided into the resulting deposition layer. In certain embodiments, the method may optionally utilize an additional Group III-based alloy source that does not comprise Ga (e.g., a Al-based alloy source) in combination with the Ga-based alloy.

As noted above, the Ga-based alloy can comprise an alloying element. In some aspects, the alloying element functions as a dopant in the resulting GaN-based material. In certain embodiments, the alloying element is a Group-I element (e.g., alkali metals) and/or a Group-II element (e.g., alkaline earth metals). For example, according to certain embodiments, the alloying element is lithium (Li), sodium (Na), potassium (K), rubidium (Rb), cesium (Cs), beryllium (Be), magnesium (Mg), calcium (Ca), strontium (Sr), and/or barium (Ba). In certain aspects, the alloying element may be a transition metal (e.g., zinc (Zn)). In certain embodiments, the alloying element may be a metalloid (e.g., silicon (Si)). In some embodiments, Mg is a preferred alloying element which can function as a p-type dopant in the resulting GaN-based material layer. In certain embodiments, a preferred alloying element which can function as a dopant in the resulting GaN-based material layer may be Li, Ba, Be, and/or Ca.

According to certain embodiments, the Ga-based alloy is a binary Ga-based alloy. As a non-limiting embodiment, the binary Ga-based alloy may comprise GaₓMg_{y} (e.g., Ga₅Mg₂, Ga₂Mg, Ga₂Mg₅). In certain embodiments, the Ga-based alloy is a ternary Ga-based alloy. As a non-limiting embodiment, the Ga-based alloy may comprise GaₓMg_{y}Al_{z} (e.g., GaMg₅Al₅). In certain embodiments, the Ga-based alloy may comprise four or more elements (e.g., four elements, five elements, six elements, etc.). In some such embodiments wherein the Ga-based alloy source comprises additional alloying elements, the additional alloying elements may be incorporated into the resulting deposited layer, but do not function as dopants. For example, the Ga-based alloy may comprise additional Group III elements, including Al and/or In that are incorporated into the resulting deposited layer.

The Ga-based alloy source may comprise any of a variety of suitable amounts of Ga (and other Group III elements, if present, such as Al and/or In) by atomic percent (at. %). For example, in certain embodiments, the Ga-based alloy source may comprise Ga in an amount of greater than or equal to 10 at. %, greater than or equal to 20 at. %, greater than or equal to 30 at. %, greater than or equal to 40 at. %, greater than or equal to 50 at. %, greater than or equal to 60 at. %, greater than or equal to 70 at. %, greater than or equal to 80 at. %, or greater than or equal to 90 at. %. In certain embodiments, the Ga-based alloy may comprise Ga in an amount of less than 100 at. %, less than or equal to 90 at. %, less than or equal to 80 at. %, less than or equal to 70 at. %, less than or equal to 60 at. %, less than or equal to 50 at. %, less than or equal to 40 at. %, less than or equal to 30 at. %, or less than or equal to 20 at. %. Combinations of the above recited ranges are also possible (e.g., the Ga-based alloy comprises Ga in an amount of greater than or equal to 30 at. % and less than or equal to 90 at. %, the Ga-based alloy comprises Ga in an amount of greater than or equal to 40 at. % and less than or equal to 60 at. %). In some embodiments, the amount of Ga in the Ga-based alloy may be dependent on the temperature of the Ga-based alloy.

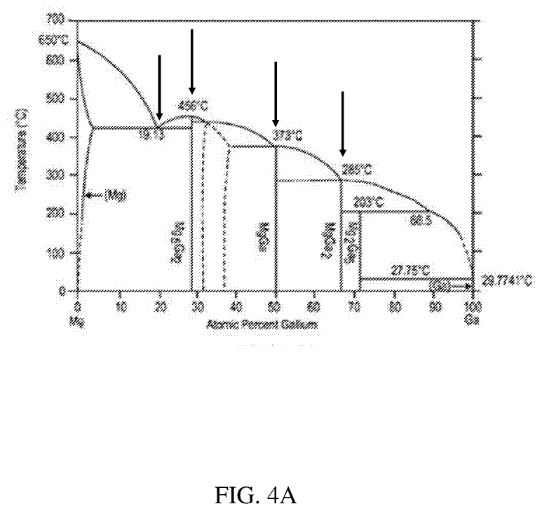

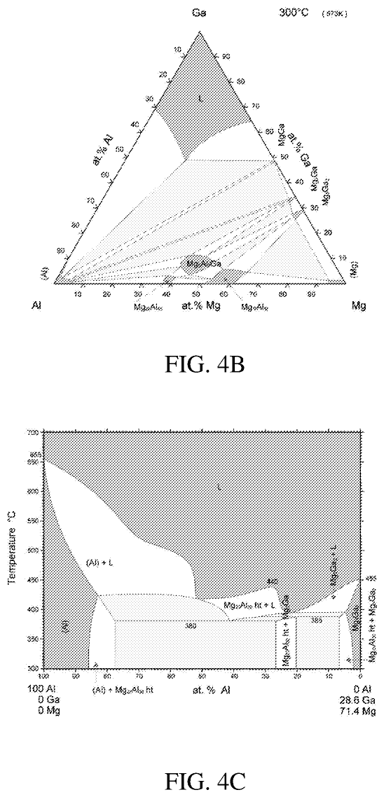

FIG. 4A, which shows a non-limiting temperature-composition phase-diagram of a Ga-based alloy comprising Mg. FIG. 4A shows various eutectic points (denoted by arrows) at which the atomic percent of Ga is precisely defined. The temperature of the eutectic composition can be purposefully tuned in order to arrive at the eutectic point. In some aspects, the eutectic point is that point at which the composition melts or solidifies that is lower than the melting point of the constituents of the composition. In reference to FIG. 4A, in certain non-limiting embodiments, the Ga-based alloy may comprise Ga in an amount of 19 at. % (e.g., Ga₂Mg₂); the Ga-based alloy may comprise Ga in an amount of 28 at. % (e.g., Ga₂Mg₂); the Ga-based alloy may comprise Ga in an amount of 50 at. % (e.g., GaMg); or the Ga-based alloy may comprise Ga in an amount of 67 at. % (e.g., Ga₂Mg). Also see FIG. 4B, which shows a non-limiting diagram of various possible compositions of a Ga-based alloy comprising Mg and Al at 300° C.

The Ga-based alloy source may comprise any suitable amount of the alloying element that functions as a dopant (e.g., Mg) in the deposited layer by atomic percent. For example, in certain embodiments, the Ga-based alloy may comprise the alloying element in an amount of greater than or equal to 1 at. %, greater than or equal to 10 at. %, greater than or equal to 20 at. %, greater than or equal to 30 at. %, greater than or equal to 40 at. %, greater than or equal to 50 at. %, greater than or equal to 60 at. %, greater than or equal to 70 at. %, or greater than or equal to 80 at. %. In certain embodiments, the Ga-based alloy may comprise the alloying element in an amount of less than or equal to 90 at. %, less than or equal to 80 at. %, less than or equal to 70 at. %, less than or equal to 60 at. %, less than or equal to 50 at. %, less than or equal to 40 at. %, less than or equal to 30% at. %, less than or equal to 20 at. %, or less than or equal to 10 at. %. Combinations of the above recited ranges are also possible (e.g., the Ga-based alloy comprises the alloying element in an amount of greater than or equal to 1 at. % and less than or equal to 30 at. %, the Ga-based alloy comprises the alloying element in an amount of greater than or equal to 10 at. % and less than or equal to 20 at. %). In certain embodiments, the amount of Ga in the Ga-based alloy may be dependent on the temperature of the Ga-based alloy.

In some non-limiting embodiments, the Ga-based alloy may comprise the alloying element in an amount of 81 at. % (e.g., Ga₂Mg₂); the Ga-based alloy may comprise the alloying element in an amount of 72 at. % (e.g., Ga₂Mg₂); the Ga-based alloy may comprise the alloying element in an amount of 50 at. % (e.g., GaMg); or the Ga-based alloy may comprise Ga in an amount of 33 at. % (e.g., Ga₂Mg). See, for example FIG. 4A and 4B. Additionally, see FIG. 4C, which shows a non-limiting temperature-composition phase-diagram of a Ga-based alloy comprising Mg and Al. As shown in FIG. 4C, the Ga-based alloy comprising Mg and Al may comprise Al in an amount of 23 at. % or 48 at. %, according to certain embodiments.

As noted above, the layer deposited onto the surface of a substrate may comprise a GaN-based material comprising the at least one alloying element as a dopant. In certain embodiments, the deposition layer is an epitaxial layer. For example, the deposition layer may have a single crystal structure. In some aspects, the deposition layer may have a polycrystalline structure. In certain aspects, the deposition layer may be at least partially amorphous.

In a certain non-limiting embodiment, the deposition layer comprises GaN. According to some non-limiting embodiments, the deposition layer comprises GaN that is doped with Mg. In an alternate non-limiting embodiment, the deposition layer may comprise AlGaN. In certain non-limiting embodiments that deposition layer comprises AlGaN that is doped with Mg.

As described above, the alloying element in the Ga-based alloy source functions as a dopant in the resulting GaN-based material deposit. According to certain embodiments, the dopant may be an electron acceptor (e.g., a p-type dopant). In certain embodiments, the dopant comprises Mg. In some embodiments, the dopant may be an electron donor (e.g., a n-type dopant). For example, in some embodiments the dopant may be Si. In some aspects, the dopant may modulate and/or enhance certain electronic properties of the resulting deposited layer (e.g., the epitaxial layer of a semiconductor material), such as the conductivity, operating voltage, current injection efficiency, and/or current spreading. For example, in certain embodiments, a deposition layer comprising an efficient dopant level from the alloying element may strategically increase the conductivity of the deposited layer as compared to a deposition layer that does not comprise a dopant from the alloying element.

According to certain embodiments, the GaN-based material layer (e.g., epitaxial layer) may have any of a variety of doping levels (e.g. concentrations of dopant). For example, in certain embodiments, the deposition layer may comprise the dopant in a concentration of greater than or equal to 10e¹⁷ cm⁻³, greater than or equal to 10e¹⁸ cm⁻³, or greater than or equal to 10e¹⁹ cm⁻³. In some embodiments, the deposition layer may comprise the dopant in a concentration of less than or equal to 10e²⁰ cm⁻³, less than or equal to 10e¹⁹ cm⁻³, or less than or equal to 10e¹⁸ cm⁻³. Combinations of the above recited ranges are also possible (e.g., the deposition layer comprises the dopant in a concentration of greater than or equal to 10e¹⁷ cm⁻³ and less than or equal to 10e²⁰ cm⁻³).

According to certain embodiments, the GaN-based material layer (e.g., the epitaxial layer) may have any of a variety of suitable thicknesses. For example, the deposition layer may be a thickness of greater than or equal to 10 Å, greater than or equal to 1,000 Å, greater than or equal to 10,000 Å, greater than or equal to 50,000 Å, or greater than or equal to 75,000 Å, etc. In certain embodiments, the deposition layer may have a thickness of less than or equal to 100,000 Å. Combinations of the above recited ranges are also possible (e.g., the deposition layer has a thickness of greater than or equal to 1,000 Å and less than or equal to 100,000 Å). The thickness of a deposition layer can be measured, in some embodiments, by microscopy techniques such as scanning electron microscopy (SEM), transmission electron microscopy (TEM), cross-sectional SEM (XSEM) and cross-sectional TEM (XTEM).

In some embodiments, the GaN-based material layer is deposited in the form of a planar layer. In other embodiments, the GaN-based material layer is deposited in a non-planar form. The GaN-based material layer may comprise a one-dimensional, two-dimensional, or three-dimensional structure. For example, the GaN-based material layer may be deposited as a shell (or other configuration) or a wire structure (e.g., nanowire). The form of the GaN-based material layer may depend on the substrate configuration, as described further below, and/or the intended application of the resulting semiconductor device.

As noted above, the methods described herein involve depositing a GaN-based material layer on a substrate. According to some embodiments, the substrate may be any of a variety of suitable substrates. For example, in certain embodiments, the substrate may comprise conventional substrate materials such as metal oxide (e.g., an aluminum oxide such as sapphire, zinc oxide, and/or magnesium oxide) or silicon (e.g., elemental silicon, silicon dioxide, and/or silicon carbide). It should be understood that the substrate may also include any number of layers deposited thereon (i.e., prior to the deposition of the GaN-based material layer described herein). For example, the substrate may include one or more additional III-nitride material-based layers deposited on a surface of the above-noted substrate materials (e.g., SiC, Si, sapphire).

As noted above, the substrate may have a variety of suitable forms. For example, the substrate may have a planar configuration. In some embodiments, the substrate may have a non-planar configuration, such as a wire (e.g., nanowire), and/or a tubular form.

In certain embodiments, the deposition layer may subsequently be separated from the substrate by any of a variety of suitable means (e.g., lift-off processes, etching, and/or photofabrication techniques such as UV-curable adhesives).

In certain embodiments, the GaN-based material layer may be used in a variety of suitable semiconductor devices including, for example, photonic devices, optoelectronic devices, high speed electronic devices, photovoltaic devices, light-emitting devices (e.g., light-emitting diodes or LEDs), and the like.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

In cases where the present specification and a document incorporated by reference include conflicting and/or inconsistent disclosure, the present specification shall control. If two or more documents incorporated by reference include conflicting and/or inconsistent disclosure with respect to each other, then the document having the later effective date shall control.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A deposition method, comprising:
providing a first material comprising a N-based source;
providing a second material comprising a Ga-based alloy, wherein the Ga-based alloy comprises Ga and at least one alloying element; and
depositing a layer comprising a GaN-based material comprising the at least one alloying element as a dopant onto a surface of a substrate.

2. The method of claim 1, wherein the first material is provided as a first gaseous composition.

3. The method of claim 1, wherein providing the second material comprises evaporating and/or vaporizing the second material into a second gaseous composition.

4. The method of claim 1, wherein the depositing is performed in a vacuum.

5. The method of claim 4, wherein the vacuum has a pressure of between or equal to 10⁻⁵ torr and 10⁻¹² torr.

6. The method of claim 1, wherein the layer comprises an epitaxial layer.

7. The method of claim 1, wherein the layer comprises GaN.

8. The method of claim 1, wherein the layer comprises AlGaN.

9. The method of claim 1, wherein the Ga-based alloy is an eutectic composition.

10. The method of claim 1, wherein the alloying element comprises a Group-I and/or Group-II element.

11. The method of claim 1, wherein the Ga-based alloy is a binary Ga-based alloy.

12. The method of claim 11, wherein the Ga-based alloy comprises GaMg.

13. The method of claim 1, wherein the Ga-based alloy is a ternary Ga-based alloy.

14. The method of claim 13, wherein the Ga-based alloy comprises GaMgAl.

15. The method of claim 1, wherein the dopant comprises Mg.

16. The method of claim 1, wherein the dopant comprises Li, Na, K, Rb, Cs, Be, Ca, Sr, Ba, Zn, and/or Si.

17. The method of claim 3, further comprising directing a molecular beam of the first gaseous composition and directing a molecular beam of the second gaseous composition at the surface of the substrate after the providing steps and before the depositing step.

18. The method of claim 2, further comprising providing a third material comprising hydrogen chloride.

19. The method of claim 18, wherein hydrogen chloride or chlorine is provided as a third gaseous composition.

20. The method of claim 1, further comprising providing a third material comprising chlorine gas.

21. The method of claim 19, further comprising reacting the second gaseous composition with the third gaseous composition to provide a gaseous metal chloride.

22. The method of claim 21, further comprising reacting the first gaseous composition with the gaseous metal chloride to form a product comprising the GaN based material.

23. The method of claim 1, wherein the depositing is performed at atmospheric pressure.
